(19) United States
(12) Patent Application Publication
(10) Pub. No.: US 2024/0339459 A1
(43) Pub. Date: Oct. 10, 2024

(54) DISPLAY DEVICE AND PREPARATION METHOD THEREFOR

(71) Applicants: Beijing BOE Technology Development Co., Ltd., Beijing (CN); BOE Technology Group Co., Ltd., Beijing (CN)

(72) Inventors: Meili Wang, Beijing (CN); Lei Wang, Beijing (CN); Wei Sun, Beijing (CN); Zhongyuan Wu, Beijing (CN); Xue Dong, Beijing (CN); Wenchao Han, Beijing (CN); Shuilang Dong, Beijing (CN)

(73) Assignees: Beijing BOE Technology Development Co., Ltd., Beijing (CN); BOE Technology Group Co., Ltd., Beijing (CN)

(21) Appl. No.: 18/580,211

(22) PCT Filed: Feb. 20, 2023
(86) PCT No.: PCT/CN2023/077147

§ 371 Date: Jan. 18, 2024

(30) Foreign Application Priority Data
Mar. 2, 2022 (CN) 202210204960.4

(51) Int. Cl. H01L 27/12

(52) U.S. Cl. CPC H01L 27/124; H01L 27/1218; H01L 27/1262

(57) ABSTRACT

A display device and a manufacturing method therefor are provided by the present application. The display devices can greatly increase the bonding precision of the chip packaging unit and the display panel, thereby the quantity of the output channels of chip packaging unit are greatly increased, thus the requirements of the high-resolution display products are satisfied. A chip packaging component is formed, wherein the chip packaging component includes at least one chip packaging unit; and the chip packaging unit includes at least a flexible base, a rigid base disposed at one side of the flexible base, and a lead layer disposed at one side of the flexible base away from the rigid base, lead layer includes at least a plurality of first leads, and orthographic projections of the plurality of first leads on the flexible base are located within an orthographic projection of rigid base on the flexible base.

### CROSS REFERENCE TO RELEVANT APPLICATIONS

The present application claims the priority of the Chinese patent application filed on Mar. 2, 2022 before the Chinese Patent Office with the application number of 202210204960.4 and the title of “DISPLAY DEVICE AND PREPARATION METHOD THEREFOR”, which is incorporated herein in its entirety by reference.

### TECHNICAL FIELD

The present application relates to the technical field of displaying and, more particularly, to a display device and a manufacturing method therefor.

### BACKGROUND

With the development of high-resolution 3D-display products, multichannel COF (Chip On Film, Flip-Chip thin film) driving is a trend in future. The COF is a chip packaging technique, i.e., a crystal-grain soft-film assembling technique for fixing a driving chip (IC) to a flexible circuit board. In 3D-display products, the COF is connected to the display panel. However, as restricted by the manufacturing processes, the bonding precision of the COF and the display panel is restricted, and the quantity of the driving channels that can be outputted is limited, which has difficulty in satisfying the requirements of high-resolution 3D-display products.

### SUMMARY

The embodiments of the present application employ the following technical solutions:

In an aspect, a manufacturing method of a display device is provided, wherein the method includes:
forming a chip packaging component, wherein the chip packaging component includes at least one chip packaging unit; and the chip packaging unit includes at least a flexible base, a rigid base disposed at one side of the flexible base, and a lead layer disposed at one side of the flexible base away from the rigid base, the lead layer includes at least a plurality of first leads, and orthographic projections of the plurality of first leads on the flexible base are located within an orthographic projection of the rigid base on the flexible base;
forming a display panel, wherein the display panel includes a non-active area, and the non-active area includes a rigid substrate and a bonding part disposed on the rigid substrate; and
bonding-connecting the first leads of the chip packaging component and the bonding part of the display panel.

Optionally, after the step of bonding-connecting the first leads of the chip packaging component and the bonding part of the display panel, the method further includes:
removing a whole of the rigid base of the chip packaging unit.

Optionally, a coefficient of thermal expansion of the rigid base and a coefficient of thermal expansion of the rigid substrate are equal.

In another aspect, a display device is provided, wherein the display device is formed by using the method for manufacturing the display device according to claim 1, and includes the chip packaging component and the display panel; the chip packaging component includes at least one chip packaging unit; the chip packaging unit includes at least the flexible base, the rigid base disposed at one side of the flexible base, and the lead layer disposed at one side of the flexible base away from the rigid base, the lead layer includes at least the plurality of first leads, and orthographic projections of the plurality of first leads on the flexible base are located within the orthographic projection of the rigid base on the flexible base; the display panel includes the non-active area, and the non-active area includes the rigid substrate and the bonding part disposed on the rigid substrate; and the first leads of the chip packaging component and the bonding part of the display panel are bonding-connected; or

the display device is formed by using the method for manufacturing the display device stated above, and includes the chip packaging component and the display panel; the chip packaging component includes at least one chip packaging unit; the chip packaging unit includes the flexible base, and the lead layer disposed at one side of the flexible base, and the lead layer includes at least the plurality of first leads; the display panel includes the non-active area, and the non-active area includes the rigid substrate and a bonding part disposed on the rigid substrate; and the first leads of the chip packaging component and the bonding part of the display panel are bonding-connected.

Optionally, a distance from each of the first leads to the flexible base in a direction perpendicular to the flexible base is greater than a distance from a neighboring part of the first lead to the flexible base in the direction perpendicular to the flexible base.

Optionally, wherein a range of a difference between the distance from each of the first leads to the flexible base in the direction perpendicular to the flexible base and the distance from the neighboring part of each of the first leads to the flexible base in the direction perpendicular to the flexible base is 2-8 micrometers.

Optionally, the chip packaging unit further includes one or more lead-wire units, and the lead-wire units are disposed between the lead layer and the flexible base; in an entirety formed by all of the lead-wire units, a distance from a part not covered by the first leads to the flexible base in the direction perpendicular to the flexible base is less than a distance from a part covered by the first leads to the flexible base in the direction perpendicular to the flexible base; the flexible base has a uniform thickness in the direction perpendicular to the flexible base; and
each of the lead-wire units includes a first lead-wire layer and a first organic layer, and the first organic layer covers the first lead-wire layer; the first lead-wire layer includes at least a plurality of first traces and/or a plurality of first trace leads; and the first traces and/or the first trace leads are electrically connected to the corresponding first leads.

Optionally, among all of the lead-wire units, in the first organic layer of the lead-wire unit contacted with the first lead, and the distance from the part not covered by the first leads to the flexible base in the direction perpendicular to the flexible base is less than the distance from the part covered by the first leads to the flexible base in the direction perpendicular to the flexible base; and
the other of the lead-wire units has a uniform thickness in the direction perpendicular to the flexible base.

Optionally, the chip packaging unit further includes a water-oxygen insulating layer, the water-oxygen insulating layer covers the flexible base, and the lead layer is disposed at one side of the water-oxygen insulating layer away from the flexible base; and
in the flexible base, a thickness of a part not covered by the first leads is less than a thickness of a part covered by the first leads.

Optionally, each of the first leads includes at least one conducting layer, and a material of the conducting layer includes a metal or a metal alloy.

Optionally, when the first lead includes one conducting layer, the first lead further includes an anti-oxidation layer, and the anti-oxidation layer covers the conducting layer.

Optionally, when the first lead includes a plurality of conducting layers, the first lead includes a first conducting layer, a second conducting layer and a third conducting layer that are arranged in layer configuration on the flexible base;
wherein each of a thickness of the first conducting layer in a direction perpendicular to the flexible base and a thickness of the third conducting layer in the direction perpendicular to the flexible base is less than a thickness of the second conducting layer in the direction perpendicular to the flexible base.

Optionally, a material of the first conducting layer and a material of the third conducting layer are the same, and the material of the first conducting layer and a material of the second conducting layer are different.

Optionally, the chip packaging unit further includes one or more lead-wire units, and the lead-wire units are disposed between the lead layer and the flexible base; each of the lead-wire units includes a first lead-wire layer and a first organic layer, and the first organic layer covers the first lead-wire layer;
the first lead-wire layer includes a plurality of first traces, and a layer structure included by the first traces and a layer structure included by the first leads are the same; and/or
the first lead-wire layer includes a plurality of first trace leads, and a layer structure included by the first trace leads and a layer structure included by the first leads are the same.

Optionally, the chip packaging unit further includes one or more lead-wire units, and the lead-wire units are disposed between the lead layer and the flexible base; each of the lead-wire units includes a first lead-wire layer and a first organic layer, and the first organic layer covers the first lead-wire layer; and
the first lead-wire layer includes a plurality of first traces, each of the first traces includes a plurality of conducting layers arranged in layer configuration, and each of the first leads includes one conducting layer; and/or
the first lead-wire layer includes a plurality of first trace leads, each of the first trace leads includes a plurality of conducting layers arranged in layer configuration, and each of the first leads includes one conducting layer.

Optionally, the plurality of first leads are arranged in an array.

Optionally, the lead layer further includes a plurality of second leads, the plurality of second leads are disposed at one side of the flexible base, the display device further includes a driving board, and the plurality of second leads are bonding-connected to the driving board.

Optionally, the second leads are disposed in the same layer as the first leads.

Optionally, the chip packaging unit further includes a chip, and the first leads and the second leads are electrically connected to the chip.

Optionally, the display panel further includes an active area connected to the non-active area; and
a length in a predetermined direction of one side of the chip packaging component that is bonded to the display panel, a length in the predetermined direction of the bonding part of the display panel and a length in the predetermined direction of the active area of the display panel are equal.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the prior art, the figures that are required to describe the embodiments or the prior art will be briefly described below. Apparently, the figures that are described below are merely embodiments of the present application, and a person skilled in the art can obtain other figures according to these figures without paying creative work.

FIG. 1 is a schematic structural diagram of a chip packaging unit according to an embodiment of the present application;

FIG. 2 is a schematic structural diagram of a display panel according to an embodiment of the present application;

FIG. 3 is a schematic structural diagram after FIG. 1 and FIG. 2 are bonded;

FIG. 4 is a schematic structural diagram after the rigid base in FIG. 3 are stripped:

FIG. 5, FIG. 6a, FIG. 6b and FIG. 7 are schematic structural diagrams after four types of chip packaging units according to the embodiments of the present application are bent;

FIG. 8 is a schematic structural diagram of another chip packaging unit according to an embodiment of the present application;

FIG. 9 is a schematic structural diagram of a chip packaging unit of single-layer trace according to an embodiment of the present application:

FIG. 10 is a cross-sectional view along the direction of CC1 of FIG. 9;

FIG. 11 is a cross-sectional view along the direction of C2C3 of FIG. 9;

FIG. 12 is a schematic structural diagram of a first lead-wire layer according to an embodiment of the present application;

FIG. 13 is a schematic structural diagram of a lead layer according to an embodiment of the present application;

FIG. 14 is a schematic structural diagram of a chip packaging unit including two layers of traces;

FIG. 15 is a cross-sectional view along the direction of EE1 of FIG. 14;

FIG. 16 is a cross-sectional view along the direction of E2E3 of FIG. 14;

FIG. 17 is a schematic structural diagram of a chip packaging unit including two lead-wire units;

FIG. 18 is a schematic structural diagram of yet another chip packaging unit according to an embodiment of the present application;

FIG. 19 and FIG. 20 are schematic structural diagrams of two types of chip packaging component including two chips according to the embodiments of the present application;

FIG. 21-FIG. 24 are schematic structural diagrams of four types of arrangement of a plurality of first leads according to the embodiments of the present application:

FIG. 25 is a schematic structural diagram of a display device according to an embodiment of the present application; and

FIG. 26-FIG. 27 are schematic structural diagrams of two types of display panel and chip packaging component according to the embodiments of the present application.

### DETAILED DESCRIPTION

The technical solutions of the embodiments of the present application will be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In the embodiments of the present application, terms such as “first”, “second” and “third” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, the meaning of “plurality of” is “two or more”, and the meaning of “at least one” is “one or more”, unless explicitly and particularly defined otherwise.

In the embodiments of the present application, the terms that indicate orientation or position relations, such as “upper” and “lower”, are based on the orientation or position relations shown in the drawings, and are merely for conveniently describing the present application and simplifying the description, rather than indicating or implying that the device or element must have the specific orientation and be constructed and operated according to the specific orientation. Therefore, they should not be construed as a limitation on the present application.

A method for manufacturing a display device is provided by an embodiment of the present application, wherein the method includes:

S01: forming a chip packaging component, wherein the chip packaging component includes at least one chip packaging unit 1 shown in FIG. 1; and the chip packaging unit 1 includes at least a flexible base 11, a rigid base 10 disposed at one side of the flexible base 11, and a lead layer 12 disposed at the side of the flexible base 11 away from the rigid base 10, the lead layer includes at least a plurality of first leads (not shown in FIG. 1), and the orthographic projections of the plurality of first leads on the flexible base are located within the orthographic projection of the rigid base on the flexible base.

The material of the flexible base is not limited. As an example, the material of the flexible base may include a flexible material such as polyimide (PI). The material of the rigid base is not limited. As an example, the material of the rigid base may include a rigid material such as glass.

The specific method for forming the chip packaging component may be determined according to the specific structure. As an example, the rigid base, the flexible base and the lead layer may be formed sequentially.

It should be noted that the rigid base of the chip packaging unit may face the whole face of the flexible base, as shown in FIG. 1. Alternatively, it may also be disposed merely within the region corresponding to the first leads. Alternatively, it may also be disposed within the region corresponding to the first leads and other bonding regions (for example, a chip bonding region and/or a driving-board bonding region).

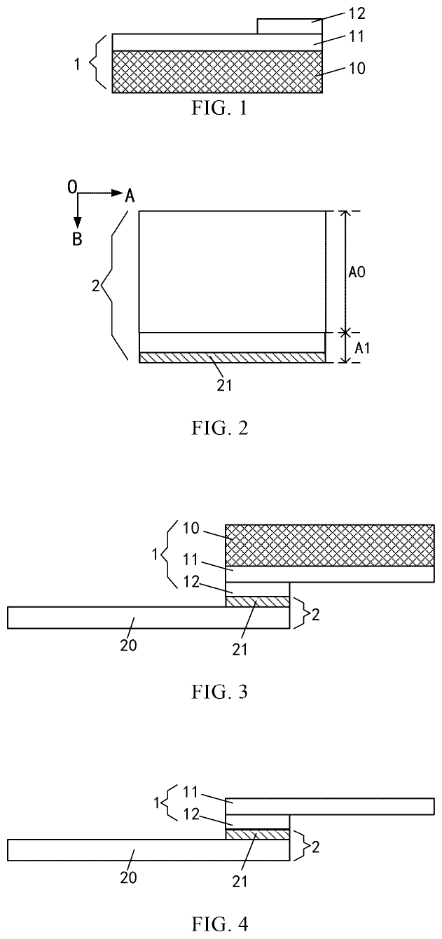

S02: forming a display panel shown in FIG. 2, wherein the display panel 2 includes a non-active area A1, and the non-active area A1 includes a rigid substrate and a bonding part 21 disposed on the rigid substrate.

The type of the display panel is not limited herein. It may be liquid-crystal display panels such as the TN (Twisted Nematic) type, the VA (Vertical Alignment) type, the IPS (In-Plane Switching) type and the ADS (Advanced Super Dimension Switch) type, and may also be an OLED (Organic Light Emitting Diode) display panel.

The material of the rigid substrate is not limited. As an example, the material of the rigid substrate may include a rigid material such as glass. The material of the rigid substrate may be the same as the material of the rigid base of the chip packaging unit, at this moment the coefficients of thermal expansion of the materials of the material of the rigid substrate and the material of the rigid base of the chip packaging unit are equal.

The display panel may further include an active area (AA), and the active area is connected to the non-active area. The active area refers to the region used to implement the displaying. The non-active area is generally used to dispose the driving circuits and so on.

S03: bonding-connecting the first leads of the chip packaging component and the bonding part of the display panel, to obtain the structure shown in FIG. 3.

In the related art, the chip packaging component includes a PI flexible matrix, the display panel includes a glass matrix, and the coefficients of thermal expansion of PI and glass are unequal. In a bonding process, it is required to employ temperature compensation; in other words, the upper base board and the lower base board are heated at different temperatures, thereby alignment of the upper base board and the lower base board is realized. Although the compensation can be partially realized, in the process of practical operation, there are a low position-aligning precision, a high loss in yield and a low bonding precision. In view of that, in the chip packaging component according to the present application, the orthographic projections of the plurality of first leads on the flexible base are located within the orthographic projection of the rigid base on the flexible base. At a same time, the bonding part of the display panel is disposed on the rigid substrate, and the coefficients of thermal expansion of the rigid base and the rigid substrate are equal or close. In the bonding process of the step S03, the compensation amount introduced by thermal expansion can be reduced to the utmost extent, thereby a high-precision bonding is realized.

Optionally, in order to save the room to the largest extent, to reduce the product size and facilitate the bending at a same time, after the step S03 of bonding-connecting the first leads of the chip packaging component and the bonding part of the display panel, the method further includes:

S04: removing a whole of the rigid base of the chip packaging unit, to obtain the structure shown in FIG. 4.

As an example, it may be stripped by laser stripping (LLO), thermal dissociation, mechanical dissociation and so on.

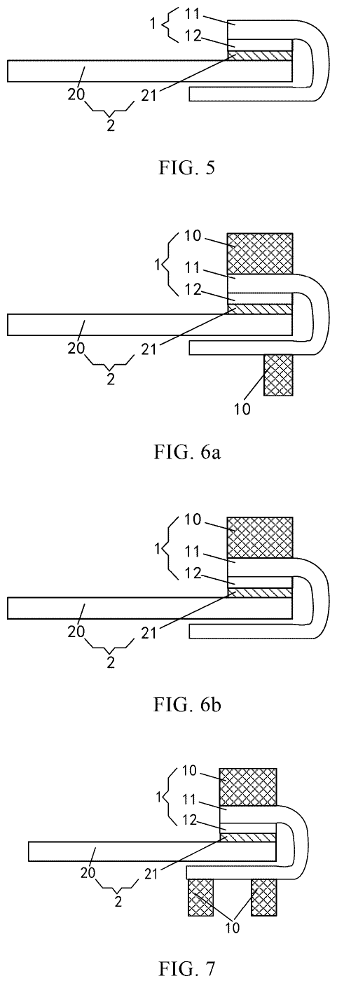

It should be noted that, after the step S03, the rigid base may also be maintained, or after being thinned by grinding and so on, the rigid base is subsequently taken into the terminal, which may be selected specifically according to practical demands. In order to further reduce the border frame, after the step S04, the chip packaging component is bent, to form the three structures shown in FIG. 5-FIG. 7. In FIG. 5, the whole of the rigid base of the chip packaging unit included by the terminal product is not maintained. In FIG. 6a, the rigid base of the chip packaging unit included by the terminal product within the region corresponding to the first leads and within the chip bonding region is maintained. In FIG. 6b, the rigid base of the chip packaging unit included by the terminal product within the region corresponding to the first leads is maintained. In FIG. 7, the rigid base of the chip packaging unit included by the terminal product within the region corresponding to the first leads, within the chip bonding region and within the driving-board bonding region is maintained.

Optionally, the coefficient of thermal expansion of the rigid base and the coefficient of thermal expansion of the rigid substrate are equal. As an example, both of the materials of the rigid base and the rigid substrate may include glass. Certainly, the coefficients of thermal expansion of the rigid base and the rigid substrate may also be close. As an example, the material of the rigid substrate may include glass, and the material of the rigid base may include PET (Polyethylene Terephthalate).

A display device is further provided by an embodiment of the present application, wherein the display device is formed by using the manufacturing method of the steps S01-S03 stated above, and the display device includes the chip packaging component and the display panel. The chip packaging component includes at least one chip packaging unit. Referring to FIG. 6 and FIG. 7, the chip packaging unit includes at least a flexible base 11, a rigid base 10 disposed at one side of the flexible base 11, and a lead layer 12 disposed at the side of the flexible base 11 away from the rigid base, the lead layer includes at least a plurality of first leads, and the orthographic projections of the plurality of first leads on the flexible base are located within the orthographic projection of the rigid base on the flexible base. The display panel includes a non-active area, and the non-active area includes a rigid substrate 20 and a bonding part 21 disposed on the rigid substrate 20. The first leads of the chip packaging component and the bonding part of the display panel are bonding-connected.

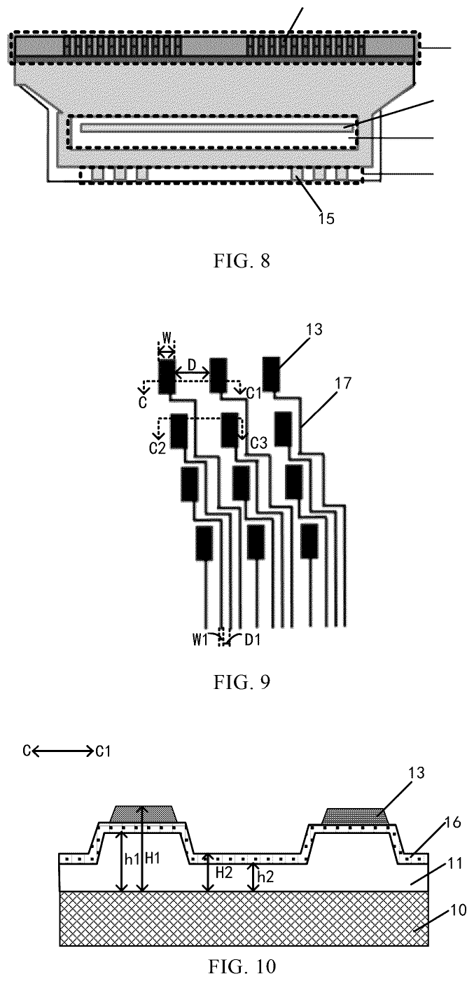

It should be noted that the chip packaging unit may include, as shown in FIG. 8, a panel bonding region B1, the chip bonding region B2, the driving-board bonding region B3 and a non-bonding region (the other region not encircled by a dotted line in FIG. 8). The panel bonding region is used to bond the display panel. The chip bonding region is used to bond the chip. The driving-board bonding region is used to bond the driving board. The first leads 13 may be disposed within the panel bonding region B1. In the chip packaging unit of the display device stated above, the rigid base may be disposed merely within the panel bonding region, or, in order to ensure the warping degree, the rigid base may be disposed within the panel bonding region and the driving-board bonding region, or the rigid base may be disposed within the panel bonding region, the chip bonding region and the driving-board bonding region, or the rigid base may be disposed at the whole region of the chip packaging unit, which is not limited herein.

Alternatively, the display device according to the embodiments of the present application may also be formed by using the manufacturing method of the steps S01-S04 stated above, and the display device includes the chip packaging component and the display panel. The chip packaging component includes at least one chip packaging unit. Referring to FIG. 4 and FIG. 5, the chip packaging unit includes a flexible base 11, and a lead layer 12 disposed at one side of the flexible base 11, and the lead layer includes at least a plurality of first leads. The display panel includes a non-active area, and the non-active area includes a rigid substrate 20 and a bonding part 21 disposed on the rigid substrate 20. The first leads of the chip packaging component and the bonding part of the display panel are bonding-connected.

The thickness of the flexible base is not limited. As an example, the range of the thickness may be 10-40 micrometers. It may be of a single-layer or multilayer structure, which is not limited herein.

In the above two types of display device, in the process of bonding the first leads of the chip packaging component and the bonding part of the display panel, the orthographic projections of the plurality of first leads on the flexible base are located within the orthographic projection of the rigid base on the flexible base. At the same time, the bonding part of the display panel is disposed on the rigid substrate, and the coefficients of thermal expansion of the rigid base and the rigid substrate are equal or close. Therefore, in the bonding process, the compensation amount introduced by thermal expansion can be reduced to the utmost extent, to reduce the bonding deviation and the bonding spacing, thereby a high-precision bonding is realized. The display devices can greatly increase the bonding precision of the chip packaging unit and the display panel, thereby the quantity of the output channels of the chip packaging unit is greatly increased, thus the requirements on high-resolution display products (for example, 3D-display products) are satisfied.

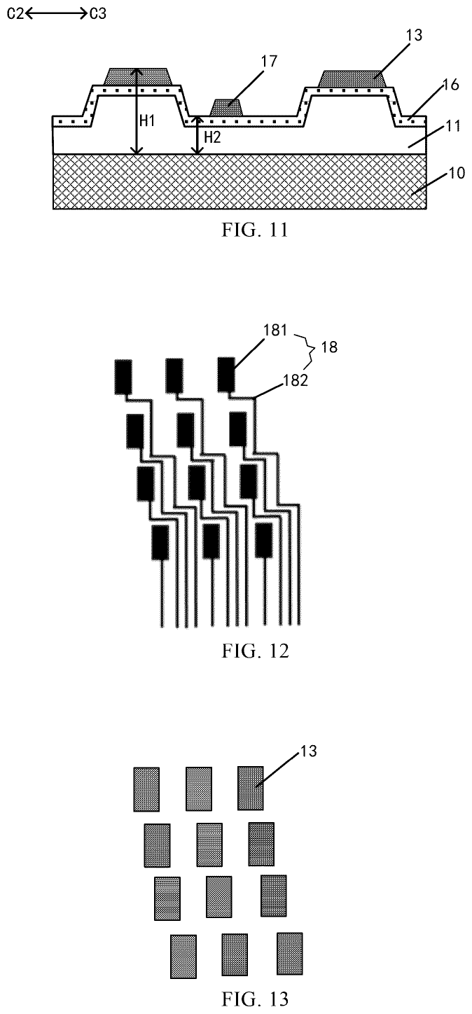

The first leads and the bonding part may be bonded by using an anisotropic electrically conductive adhesive (ACF, anisotropic Conductive Films). In order to provide a sufficient adhesive-overflowing room, to ensure the quality of the bonding, in one or more embodiments, referring to FIG. 10 and FIG. 11, the distance H1 from each of the first leads 13 to the flexible base 11 in the direction perpendicular to the flexible base 11 is greater than the distance H2 from a neighboring part of the first lead to the flexible base 11 in the direction perpendicular to the flexible base 11.

Optionally, in order to ensure a sufficient adhesive-overflowing room and reduce the product size at the same time, the range of the difference between the distance from each of the first leads to the flexible base in the direction perpendicular to the flexible base and the distance from the neighboring part of each of the first leads to the flexible base in the direction perpendicular to the flexible base is 2-8 micrometers. As an example, the difference may be 2 micrometers, 4 micrometers, 6 micrometers, 8 micrometers and so on.

The chip packaging unit may employ the single-layer-race structure shown in FIG. 10 and FIG. 11, or employ the multilayer-trace structure shown in FIG. 15 and FIG. 16, which is not limited herein.

A chip packaging unit including a plurality of layers of the traces will be provided below.

Optionally, the chip packaging unit further includes one or more lead-wire units. Referring to FIG. 15 and FIG. 16, the lead-wire units 3 are disposed between the lead layer and the flexible base 11. In an entirety formed by all of the lead-wire units, the distance H4 from the part not covered by the first leads to the flexible base in the direction perpendicular to the flexible base is less than the distance H3 from the part covered by the first leads to the flexible base in the direction perpendicular to the flexible base. The flexible base has a uniform thickness H in the direction perpendicular to the flexible base.

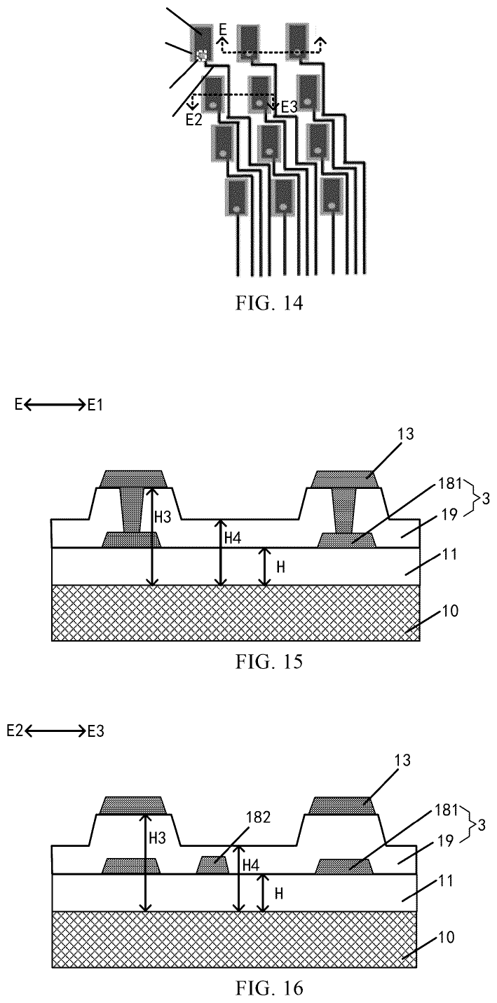

Referring to FIGS. 12 and 14-16, each of the lead-wire units 3 includes a first lead-wire layer 18 and a first organic layer 19, and the first organic layer 19 covers the first lead-wire layer 18. The first lead-wire layer 18 includes at least a plurality of first traces 182 and/or a plurality of first trace leads 181. The first traces 182 and/or the first trace leads 181 are electrically connected to the corresponding first leads 13. As an example, the first trace leads 181 may be electrically connected to the corresponding first leads 13 through the switching holes 180 shown in FIG. 14.

That the first lead-wire layer includes at least a plurality of first traces and/or a plurality of first trace leads includes three cases. In the first case, the first lead-wire layer includes at least a plurality of first traces, at this moment, the first traces are electrically connected to the corresponding first leads, and the first traces and the first leads may overlap or not overlap in the direction perpendicular to the flexible base. In the second case, the first lead-wire layer includes at least a plurality of first trace leads, at this moment, the first trace leads are electrically connected to the corresponding first leads, and at this moment, the first trace leads and the first leads may overlap or not overlap in the direction perpendicular to the flexible base. In the third case, the first lead-wire layer includes at least a plurality of first traces 182 and a plurality of first trace leads 181, as shown in FIG. 12, at this moment the first traces and the first trace leads are electrically connected to the corresponding first leads, the first traces and the first trace leads may be arranged in the same layer, and the first trace leads and the first traces may individually overlap or not overlap with the first leads in the direction perpendicular to the flexible base; in order to reduce the generation of parasitic capacitance, referring to FIG. 14, the first traces 182 and the first leads 13 do not overlap in the direction perpendicular to the flexible base; and in order to save the room and reduce the spacing, referring to FIG. 14, the first trace leads 181 and the first leads 13 overlap in the direction perpendicular to the flexible base, and, further, the orthographic projections of the first trace leads on the flexible base are located within the orthographic projections of the first leads on the flexible base. The arrangement in the same layer used herein refers to that they are fabricated by using a one-step patterning process. The one-step patterning process refers to a process that the required layer structure is formed by a single exposure. The one-step patterning process includes the processes of masking, exposure, development, etching, stripping and so on.

The specific layer structures of the first traces and the first trace leads are not limited herein. As an example, each of the first traces and the first trace leads may include one conducting layer, for example, a copper conducting layer. Alternatively, each of them may also include a plurality of conducting layers, for example, a three-layer tandem structure of a titanium conducting layer, an aluminum conducting layer and a titanium conducting layer, or a three-layer tandem structure of a molybdenum conducting layer, an aluminum conducting layer and a molybdenum conducting layer.

Herein the specific layer structures of the first traces and the first trace leads and the specific layer structure of the first leads may be the same, or may also be different, which is not limited herein.

The first organic layer may be of a single-layer structure or a multilayer structure, which is not limited herein. The thickness of the first organic layer may be 5-10 micrometers. If the first organic layer is of a multilayer structure, the materials of the organic layers may be the same or different.

In such a structure, by disposing the lead layer and the first lead-wire layer, the functions of the first leads and the first traces can be realized respectively, thereby leads of a higher quantity are further provided is realized, the quantity of the output channels of the chip packaging component is further increased.

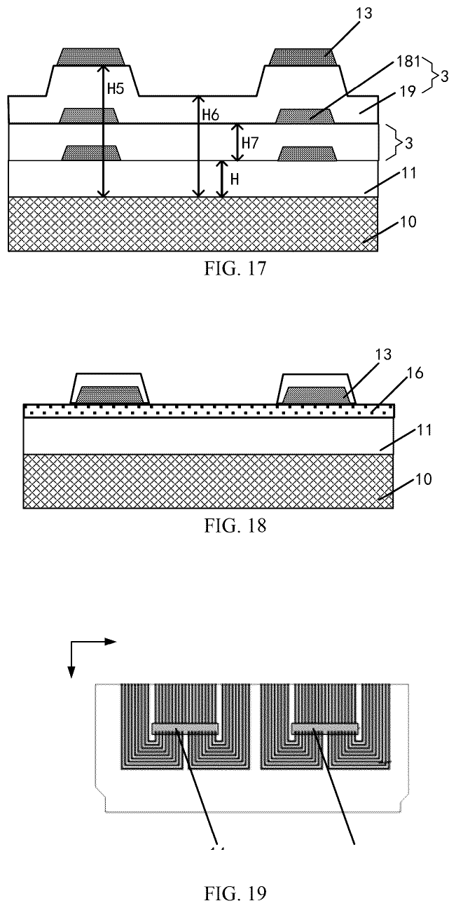

Optionally, among all of the lead-wire units, referring to FIG. 17, in the first organic layer 19 of the lead-wire unit 3 contacted with the first lead 13, the distance H6 from the part not covered by the first leads to the flexible base in the direction perpendicular to the flexible base is less than the distance H5 from the part covered by the first leads to the flexible base in the direction perpendicular to the flexible base. The other of the lead-wire units has a uniform thickness H7 in the direction perpendicular to the flexible base. Such a structure is simple and easy to implement, and it is merely required to pattern the first organic layer of the lead-wire unit contacted with the first lead, to ensure a sufficient adhesive-overflowing room. FIG. 17 is illustrated by taking the case as an example in which two lead-wire units are included.

In one or more embodiments, because the flexible base is fabricated by using an organic material, and is easily eroded by water and oxygen, in order to prevent water-oxygen erosion, the chip packaging unit further includes a water-oxygen insulating layer 16 shown in FIG. 10, the water-oxygen insulating layer 16 covers the flexible base 11, and the lead layer is disposed at the side of the water-oxygen insulating layer away from the flexible base. Referring to FIG. 10, in the flexible base 11, the thickness h2 of the part not covered by the first leads 13 is less than the thickness h1 of the part covered by the first leads. The thickness of the water-oxygen insulating layer is not limited. As an example, the range of the thickness is 100-500 nanometers. The material of the water-oxygen insulating layer may include silicon dioxide or silicon nitride.

In one or more embodiments, each of the first leads includes at least one conducting layer, and the material of the conducting layer includes a metal or a metal alloy. As an example, the material of the conducting layer may include a metal such as Mo, Al, Ti and Cu or an alloy. Taking copper as an example, the first leads may be formed by etching a thick copper plate or electroplating thick copper, and the thickness of the copper is approximately 8 micrometers. Because the isotropy of wet etching, a very low dimensional deviation (CD Bias) is difficult to obtain, and therefore the spacing between the formed leads is greater than 16 micrometers.

Optionally, if the first lead includes one conducting layer, if the first lead is fabricated by using an easily oxidized material such as copper, in order to prevent copper oxidation, the first lead further includes an anti-oxidation layer 13, and the anti-oxidation layer covers the conducting layer. The anti-oxidation layer may employ process of chemical plating of Sn and Au and so on, and the range of the thickness is 0.5 μm-2 μm. Alternatively, the surface of the first lead may also be covered by ITO (Indium Tin Oxide), to prevent oxidation. In addition, the anti-oxidation layer further facilitates to increase the height of the region where the first lead is located, to ensure a sufficient adhesive-overflowing room in the subsequent bonding with the panel.

In order to protect the non-bonding region, optionally, a solder-resist layer (for example, green oil) may be disposed within the non-bonding region of the chip packaging unit, and the range of the thickness is 5-20 micrometers.

Optionally, if the first lead includes a plurality of conducting layers, the first lead includes a first conducting layer, a second conducting layer and a third conducting layer that are arranged in layer configuration on the flexible base; and each of the thickness of the first conducting layer in the direction perpendicular to the flexible base and the thickness of the third conducting layer in the direction perpendicular to the flexible base is less than the thickness of the second conducting layer in the direction perpendicular to the flexible base.

The material of the first conducting layer and the material of the third conducting layer may be the same or different. The second conducting layer may employ a metal material such as aluminum, and the first conducting layer and the third conducting layer may employ metal materials such as molybdenum and titanium, in this way, finer wiring can be formed by the process of photoetching, electroplating and so on, and the trace spacing (pitch) can be reduced to below 16 micrometers, or even reduced to approximately several micrometers (for example, 3.6 micrometers or 5 micrometers). By contrast, if the conducting layers are fabricated by using copper, the trace spacing (pitch) is at least 16-18 micrometers. The multilayer tandem structure, as compared with the single-copper-layer structure, can reduce the wiring room to a great extent, so that the chip packaging unit can provide more output leads, to satisfy the requirements of high-resolution display products and 3D-display products. It should be noted that, as shown in FIG. 9, the trace spacing refers to the sum of the line width W1 of the trace (the trace 17 shown in FIG. 9) and the spacing DI between the neighboring traces, and the lead spacing refers to the sum of the width W of the lead (the first lead 13 shown in FIG. 9) and the spacing D between the neighboring leads.

In order to simplify the process, the material of the first conducting layer and the material of the third conducting layer are the same, and the material of the first conducting layer and the material of the second conducting layer are different. As an example, the material of the second conducting layer may include aluminum and so on, and the material of the first conducting layer and the third conducting layer may include molybdenum, titanium and so on.

In some embodiments, the chip packaging unit further includes one or more lead-wire units, and the lead-wire units are disposed between the lead layer and the flexible base. Each of the lead-wire units includes a first lead-wire layer and a first organic layer, and the first organic layer covers the first lead-wire layer.

The first lead-wire layer includes a plurality of first traces, and the layer structure included by the first traces and the layer structure included by the first leads are the same; and/or the first lead-wire layer includes a plurality of first trace leads, and the layer structure included by the first trace leads and the layer structure included by the first leads are the same.

The chip packaging unit includes three cases. In the first case, the first lead-wire layer includes a plurality of first traces, at this moment, the layer structure included by the first traces and the layer structure included by the first leads are the same. As an example, the first traces may be of a single-layer structure or a multilayer structure, which may specifically refer to the above description on the layer structure of the first leads, and is not discussed further herein. In the second case, the first lead-wire layer includes a plurality of first trace leads, and the layer structure included by the first trace leads and the layer structure included by the first leads are the same. As an example, the first traces may be of a single-layer structure or a multilayer structure, which may specifically refer to the above description on the layer structure of the first leads, and is not discussed further herein. In the third case, the first lead-wire layer includes a plurality of first traces and a plurality of first trace leads, and the first traces and the first trace leads may be of a single-layer structure or a multilayer structure, which may specifically refer to the above description on the layer structure of the first leads, and is not discussed further herein.

In some embodiments, the chip packaging unit further includes one or more lead-wire units, and the lead-wire units are disposed between the lead layer and the flexible base. Each of the lead-wire units includes a first lead-wire layer and a first organic layer, and the first organic layer covers the first lead-wire layer.

The first lead-wire layer includes a plurality of first traces, each of the first traces includes a plurality of conducting layers arranged in layer configuration, and each of the first leads includes one conducting layer; and/or the first lead-wire layer includes a plurality of first trace leads, each of the first trace leads includes a plurality of conducting layers arranged in layer configuration, and each of the first leads includes one conducting layer.

The chip packaging unit includes three cases. In the first case, the first lead-wire layer includes a plurality of first traces, each of the first traces includes a plurality of conducting layers arranged in layer configuration, and each of the first leads includes one conducting layer. As an example, each of the first traces includes a titanium conducting layer, an aluminum conducting layer and a titanium conducting layer that are arranged in layer configuration, and each of the first leads includes a copper conducting layer. In the second case, the first lead-wire layer includes a plurality of first trace leads, each of the first trace leads includes a plurality of conducting layers arranged in layer configuration, and each of the first leads includes one conducting layer. As an example, each of the first trace leads includes a titanium conducting layer, an aluminum conducting layer and a titanium conducting layer that are arranged in layer configuration, and each of the first leads includes a copper conducting layer. In the third case, the first lead-wire layer includes a plurality of first traces and a plurality of first trace leads, each of the first traces and each of the first trace leads include a plurality of conducting layers arranged in layer configuration, and each of the first leads includes one conducting layer. As an example, each of the first traces and each of the first trace leads include a titanium conducting layer, an aluminum conducting layer and a titanium conducting layer that are arranged in layer configuration, and each of the first leads includes a copper conducting layer.

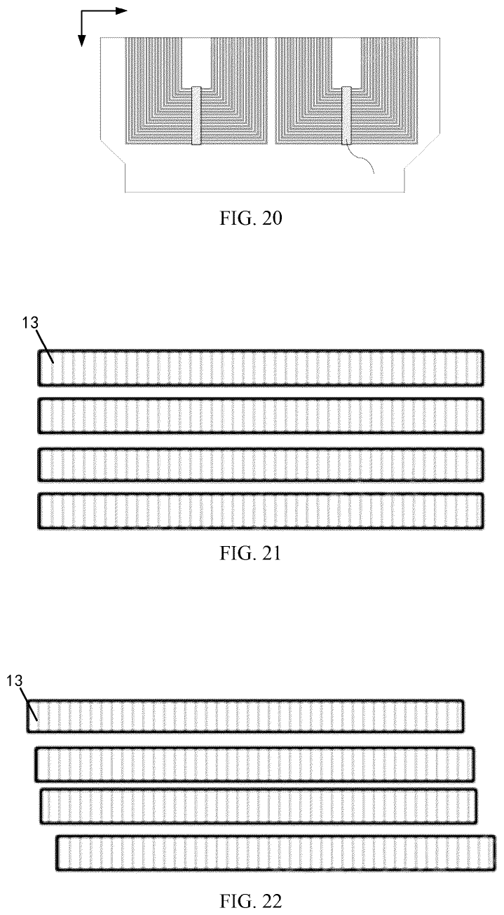

As restrained by the current factors such as silicon-wafer fabrication and cutting, usually the transverse dimension of a single IC (chip) can merely reach at most approximately 32 mm, and it is difficult to export more signal lines. In the present application, the display device includes at least one chip packaging unit, and the quantity of the chip packaging units may be selected according to the size of the product. If the display device includes a plurality of chip packaging units, the modes of arranging the chips included by the chip packaging units are not limited. As an example, the chips 14 may be arranged horizontally in the direction OA as shown in FIG. 19. Alternatively, the chips 14 may be arranged vertically in the direction OB as shown in FIG. 20. Alternatively, some of chips are arranged horizontally, and some of chips are arranged vertically, which is not limited herein.

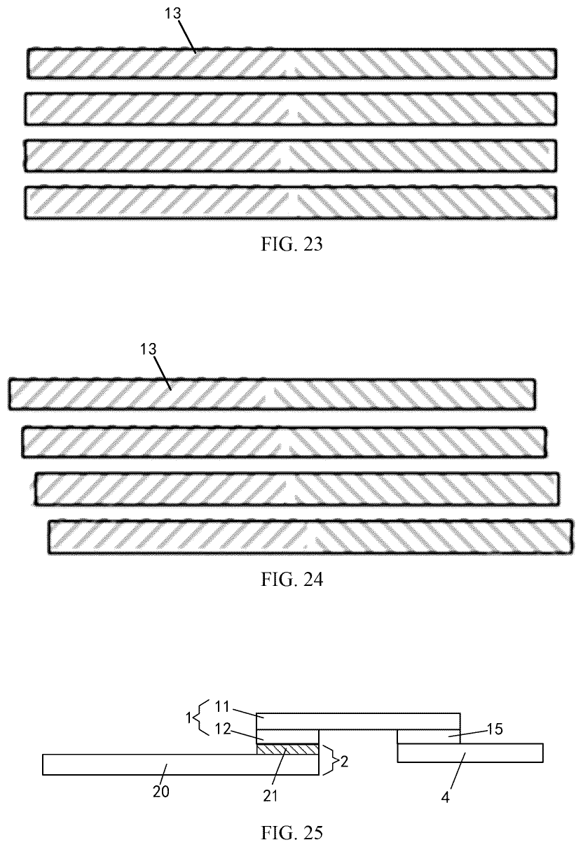

In addition, the sizes of the chips are restricted, and the modes of arranging the plurality of leads in the chip packaging units also influence the quantity of the output channels. Optionally, the plurality of first leads are arranged in an array. As an example, the plurality of first leads may be arranged in a plurality of rows, for example, in 2 rows, 3 rows, 4 rows (as shown in FIG. 21-24) or 5 rows. The directions of the arrangement of the plurality of first leads in each of the rows and the directions of the arrangement of the plurality of rows are not limited. As an example, the plurality of rows may be arranged vertically as shown in FIG. 21, or arranged obliquely as shown in FIG. 22. In each of the rows, the first leads may be arranged vertically as shown in FIGS. 21 and 22, or arranged obliquely as shown in FIGS. 23 and 24, thereby a reverse-V-shaped arrangement is formed. The total length of the plurality of first leads may be 60 mm. 68 mm, 70 mm, 127 mm or higher, which may specifically be regulated according to the length of the panel.

In one or more embodiments, the lead layer further includes a plurality of second leads 15 shown in FIGS. 8 and 25, and the plurality of second leads 15 are disposed at one side of the flexible base. Referring to FIG. 25, the display device further includes a driving board 4, and the plurality of second leads 15 are bonding-connected to the driving board 4.

Herein the driving board may be a PCB (Printed Circuit Board) circuit board, and may also be an FPC (Flexible Printed Circuit) circuit board. In order to further reduce the border frame, the latter may be selected.

Optionally, in order to simplify the process and reduce the cost, the second leads are disposed in the same layer as the first leads. The layer structures included by the second leads and the first leads are the same. As an example, the second leads may be of a single-layer structure or a multilayer structure, which may specifically refer to the above description on the layer structure of the first leads, and is not discussed further herein.

Optionally, the chip packaging unit further includes a chip (IC) shown in FIG. 8, and the first leads 13 and the second leads 15 are electrically connected to the chip 14. Because the quantity of the second leads bonding-connected to the driving board is less than the quantity of the first leads bonding-connected to the display panel, the excessive second leads may also be bonded to the display panel, thereby the output channels are further increased, and the room is saved at a same time. In order to protect the chips, a packaging layer may be disposed, for example, a resin layer.

In one or more embodiments, the display panel further includes an active area connected to the non-active area. The length in a predetermined direction of the side of the chip packaging component that is bonded to the display panel, the length in the predetermined direction of the bonding part of the display panel and the length in the predetermined direction of the active area of the display panel are equal.

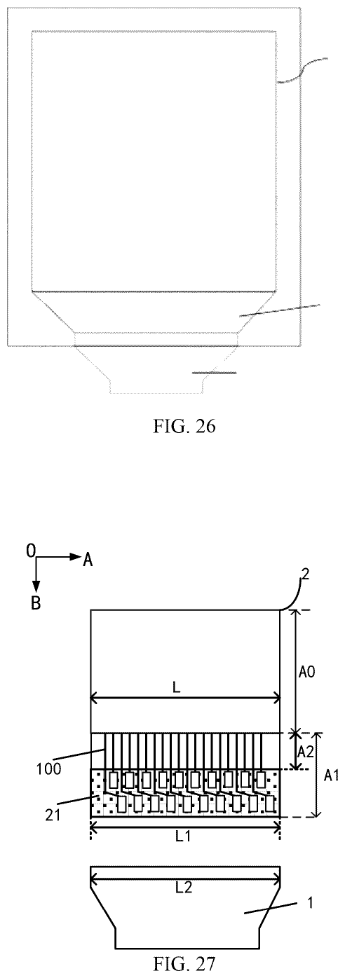

In the related art, the size of the COFs using the PI-based is restricted. When the display panel is bonded to a COF, in order to match the display panel with the size of the COF, it is required to dispose within the non-active area a sector-shaped lead-wire region (Fanout region) A2 shown in FIG. 26, the lead wires are collected within a certain region, and subsequently connected to the bonding part. In order to ensure equal-resistance wiring, the lead wires within the lead-wire region are arranged in a π shape and so on, which results in a large occupied room and thus a large border frame. However, the present application uses a glass base to form the chip packaging component, the sizes are not restricted. Referring to FIG. 27, the length L2 in a predetermined direction (the direction OA shown in FIG. 27) of the side of the chip packaging component that is bonded to the display panel, the length L1 in the predetermined direction (the direction OA shown in FIG. 27) of the bonding part of the display panel and the length L in the predetermined direction (the direction OA shown in FIG. 27) of the active area A0 of the display panel are equal. Accordingly, the lead wires 100 of the display panel can be exported directly in the direction (the direction OB shown in FIG. 27) perpendicular to the predetermined direction, and electrically connected to the bonding part, which does not require to dispose the equal-resistance wiring, thereby the border frame is reduced to the largest extent, to facilitate the formation of ultra-narrow-border-frame display products.

The “one embodiment”, “an embodiment” or “one or more embodiments” as used herein means that particular features, structures or characteristics described with reference to an embodiment are included in at least one embodiment of the present application. Moreover, it should be noted that here an example using the wording “in an embodiment” does not necessarily refer to the same embodiment.

The description provided herein describes many concrete details. However, it can be understood that the embodiments of the present application may be implemented without those concrete details. In some of the embodiments, well-known processes, structures and techniques are not described in detail, so as not to affect the understanding of the description.

Finally, it should be noted that the above embodiments are merely intended to explain the technical solutions of the present application, and not to limit them. Although the present application is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present application.

1. A method for manufacturing a display device, wherein the method comprises:
forming a chip packaging component, wherein the chip packaging component comprises at least one chip packaging unit; and the chip packaging unit comprises at least a flexible base, a rigid base disposed at one side of the flexible base, and a lead layer disposed at one side of the flexible base away from the rigid base, the lead layer comprises at least a plurality of first leads, and orthographic projections of the plurality of first leads on the flexible base are located within an orthographic projection of the rigid base on the flexible base;
forming a display panel, wherein the display panel comprises a non-active area, and the non-active area comprises a rigid substrate and a bonding part disposed on the rigid substrate; and
bonding-connecting the first leads of the chip packaging component and the bonding part of the display panel.

2. The method for manufacturing the display device according to claim 1, wherein after the step of bonding-connecting the first leads of the chip packaging component and the bonding part of the display panel, the method further comprises:
removing a whole of the rigid base of the chip packaging unit.

3. The method for manufacturing the display device according to claim 1, wherein a coefficient of thermal expansion of the rigid base and a coefficient of thermal expansion of the rigid substrate are equal.

4. A display device, wherein the display device is formed by using the method for manufacturing the display device according to claim 1, and comprises the chip packaging component and the display panel; the chip packaging component comprises at least one chip packaging unit; the chip packaging unit comprises at least the flexible base, the rigid base disposed at one side of the flexible base, and the lead layer disposed at one side of the flexible base away from the rigid base, the lead layer comprises at least the plurality of first leads, and orthographic projections of the plurality of first leads on the flexible base are located within the orthographic projection of the rigid base on the flexible base; the display panel comprises the non-active area, and the non-active area comprises the rigid substrate and the bonding part disposed on the rigid substrate; and the first leads of the chip packaging component and the bonding part of the display panel are bonding-connected.

5. The display device according to claim 4, wherein a distance from each of the first leads to the flexible base in a direction perpendicular to the flexible base is greater than a distance from a neighboring part of the first lead to the flexible base in the direction perpendicular to the flexible base.

6. The display device according to claim 5, wherein a range of a difference between the distance from each of the first leads to the flexible base in the direction perpendicular to the flexible base and the distance from the neighboring part of each of the first leads to the flexible base in the direction perpendicular to the flexible base is 2-8 micrometers.

7. The display device according to claim 5, wherein the chip packaging unit further comprises one or more lead-wire units, and the lead-wire units are disposed between the lead layer and the flexible base; in an entirety formed by all of the lead-wire units, a distance from a part not covered by the first leads to the flexible base in the direction perpendicular to the flexible base is less than a distance from a part covered by the first leads to the flexible base in the direction perpendicular to the flexible base: the flexible base has a uniform thickness in the direction perpendicular to the flexible base; and
each of the lead-wire units comprises a first lead-wire layer and a first organic layer, and the first organic layer covers the first lead-wire layer; the first lead-wire layer comprises at least a plurality of first traces and/or a plurality of first trace leads; and the first traces and/or the first trace leads are electrically connected to the corresponding first leads.

8. The display device according to claim 7, wherein among all of the lead-wire units, in the first organic layer of the lead-wire unit contacted with the first lead, and the distance from the part not covered by the first leads to the flexible base in the direction perpendicular to the flexible base is less than the distance from the part covered by the first leads to the flexible base in the direction perpendicular to the flexible base; and
the other of the lead-wire units has a uniform thickness in the direction perpendicular to the flexible base.

9. The display device according to claim 5, wherein the chip packaging unit further comprises a water-oxygen insulating layer, the water-oxygen insulating layer covers the flexible base, and the lead layer is disposed at one side of the water-oxygen insulating layer away from the flexible base; and
in the flexible base, a thickness of a part not covered by the first leads is less than a thickness of a part covered by the first leads.

10. The display device according to claim 4, wherein each of the first leads comprises at least one conducting layer, and a material of the conducting layer comprises a metal or a metal alloy.

11. The display device according to claim 10, wherein when the first lead comprises one conducting layer, the first lead further comprises an anti-oxidation layer, and the anti-oxidation layer covers the conducting layer.

12. The display device according to claim 10, wherein when the first lead comprises a plurality of conducting layers, the first lead comprises a first conducting layer, a second conducting layer and a third conducting layer that are arranged in layer configuration on the flexible base;
wherein each of a thickness of the first conducting layer in a direction perpendicular to the flexible base and a thickness of the third conducting layer in the direction perpendicular to the flexible base is less than a thickness of the second conducting layer in the direction perpendicular to the flexible base.

13. The display device according to claim 12, wherein a material of the first conducting layer and a material of the third conducting layer are the same, and the material of the first conducting layer and a material of the second conducting layer are different.

14. The display device according to claim 10, wherein the chip packaging unit further comprises one or more lead-wire units, and the lead-wire units are disposed between the lead layer and the flexible base; each of the lead-wire units comprises a first lead-wire layer and a first organic layer, and the first organic layer covers the first lead-wire layer;
the first lead-wire layer comprises a plurality of first traces, and a layer structure comprised by the first traces and a layer structure comprised by the first leads are the same; and/or
the first lead-wire layer comprises a plurality of first trace leads, and a layer structure comprised by the first trace leads and a layer structure comprised by the first leads are the same.

15. The display device according to claim 10, wherein the chip packaging unit further comprises one or more lead-wire units, and the lead-wire units are disposed between the lead layer and the flexible base; each of the lead-wire units comprises a first lead-wire layer and a first organic layer, and the first organic layer covers the first lead-wire layer; and
the first lead-wire layer comprises a plurality of first traces, each of the first traces comprises a plurality of conducting layers arranged in layer configuration, and each of the first leads comprises one conducting layer; and/or
the first lead-wire layer comprises a plurality of first trace leads, each of the first trace leads comprises a plurality of conducting layers arranged in layer configuration, and each of the first leads comprises one conducting layer.

16. The display device according to claim 4, wherein the plurality of first leads are arranged in an array.

17. The display device according to claim 4, wherein the lead layer further comprises a plurality of second leads, the plurality of second leads are disposed at one side of the flexible base, the display device further comprises a driving board, and the plurality of second leads are bonding-connected to the driving board.

18. The display device according to claim 17, wherein the second leads are disposed in the same layer as the first leads.

19. The display device according to claim 18, wherein the chip packaging unit further comprises a chip, and the first leads and the second leads are electrically connected to the chip.

20. The display device according to claim 4, wherein the display panel further comprises an active area connected to the non-active area; and
a length in a predetermined direction of one side of the chip packaging component that is bonded to the display panel, a length in the predetermined direction of the bonding part of the display panel and a length in the predetermined direction of the active area of the display panel are equal.
